(19) United States
(12) Patent Application Publication
(10) Pub. No.: US 2025/0227925 A1
(43) Pub. Date: Jul. 10, 2025

(54) SEMICONDUCTOR DEVICE

(71) Applicant: Samsung Electronics Co., Ltd., Suwon-si (KR)

(72) Inventors: Gayoung KWON, Suwon-si (KR); Jihye PARK, Suwon-si (KR); Youngseok KIM, Suwon-si (KR); Miri PARK, Suwon-si (KR)

(73) Assignee: Samsung Electronics Co., Ltd., Suwon-si (KR)

(21) Appl. No.: 18/932,739

(22) Filed: Oct. 31, 2024

(30) Foreign Application Priority Data
Jan. 9, 2024 (KR) 10-2024-0003369

(51) Int. Cl. H10B 12/00

(52) U.S. Cl. CPC H10B 12/50; H10B 12/09; H10B 12/315

(57) ABSTRACT

A semiconductor device includes lower electrodes on a substrate, a dielectric layer covering the lower electrodes, an upper electrode on the dielectric layer, and a mask pattern on the upper electrode. The upper electrode includes a first pattern covering upper surfaces and sidewalls of the lower electrodes and a second pattern on the first pattern. An end of the first pattern, an end of the second pattern, and an end of the mask pattern are aligned in a direction perpendicular to the substrate.

### CROSS-REFERENCE TO RELATED APPLICATIONS

This U.S. non-provisional patent application claims priority under 35 U.S.C. § 119 to Korean Patent Application No. 10-2024-0003369 filed on Jan. 9, 2024, in the Korean Intellectual Property Office, the entire contents of which are hereby incorporated by reference.

### BACKGROUND OF THE INVENTION

The inventive concepts relate to semiconductor devices, and more specifically, relates to semiconductor memory devices including a capacitor.

Semiconductor devices are widely used in the electronics industry due to their small size, multi-functional characteristics and/or low manufacturing costs. Semiconductor devices may be classified into semiconductor memory devices that store logical data, semiconductor logical devices that perform a logical data operation process, and hybrid semiconductor devices including memory elements and logical elements.

In view of the recent trend of high speed and low power consumption of electronic devices, semiconductor devices in the electronic devices are being developed to provide high operating speeds and/or low operating voltages. Accordingly, there is a demand for increased integration density of the semiconductor device. However, as the integration density of the semiconductor device increases, the semiconductor device may suffer from deterioration in electric characteristics and production yield. Accordingly, many studies are being conducted to increase the electric characteristics and production yield of the semiconductor device.

### SUMMARY

An aspect of the inventive concepts is to provide to a semiconductor device with improved electrical characteristics.

An aspect of the inventive concepts is to provide to a semiconductor device with improved integration.

The aspects of the inventive concepts are not limited to the aspects mentioned above, and other aspects not mentioned will be clearly understood by those skilled in the art from the description below.

A semiconductor device according to some example embodiments of the inventive concepts may include lower electrodes on a substrate, a dielectric layer covering the lower electrodes, an upper electrode on the dielectric layer, and a mask pattern on the upper electrode, wherein the upper electrode includes a first pattern covering upper surfaces and sidewalls of the lower electrodes and a second pattern on the first pattern, and an end of the first pattern, an end of the second pattern, and an end of the mask pattern are aligned in a direction perpendicular to the substrate.

A semiconductor device according to some example embodiments of the inventive concepts may include lower electrodes on a substrate, a dielectric layer covering the lower electrodes, and an upper electrode on the dielectric layer, wherein the upper electrode includes a first pattern covering upper surface and sidewalls of the lower electrodes and a second pattern on the first pattern, the second pattern is thinner than the first pattern, and an end of the second pattern is on the first pattern.

A semiconductor device according to some example embodiments of the inventive concepts may include active regions including a first impurity region and a second impurity region and defined by a device isolation layer, on a substrate, word lines extending in a first direction on the active regions, capping insulating patterns covering upper surfaces of the word lines, respectively, bit lines extending on the word lines in a second direction intersecting the first direction, contact plugs between the bit lines and connected to the second impurity region, and a capacitor on each of the contact plugs, wherein the capacitor includes lower electrodes on the substrate, a support pattern between the lower electrodes, an upper electrode covering the lower electrodes and the support pattern, a mask pattern on the upper electrode, and a dielectric layer between lower electrodes covering the mask pattern and the upper electrode, and between the support pattern and the upper electrode, the upper electrode includes a first pattern covering upper surfaces of the lower electrodes, a second pattern covering the first pattern, and an end of the first pattern, an end of the second pattern, and an end of the mask pattern are aligned in a direction perpendicular to the substrate.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view showing a semiconductor device according to some example embodiments of the inventive concepts.

FIG. 2 is an enlarged view of region ‘P1’ in FIG. 1.

FIG. 3 is a cross-sectional view corresponding to A-A′ in FIG. 1.

FIGS. 4 to 11 are cross-sectional views for explaining a method of manufacturing a semiconductor device according to some example embodiments of the inventive concepts.

FIG. 12 is a cross-sectional view of a semiconductor device according to some example embodiments of the inventive concepts.

FIGS. 13 to 15 are cross-sectional views for explaining a method of manufacturing a semiconductor device according to some example embodiments of the inventive concepts.

### DETAILED DESCRIPTION

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, to explain the inventive concepts in detail, example embodiments according to the inventive concepts will be described with reference to the accompanying drawings.

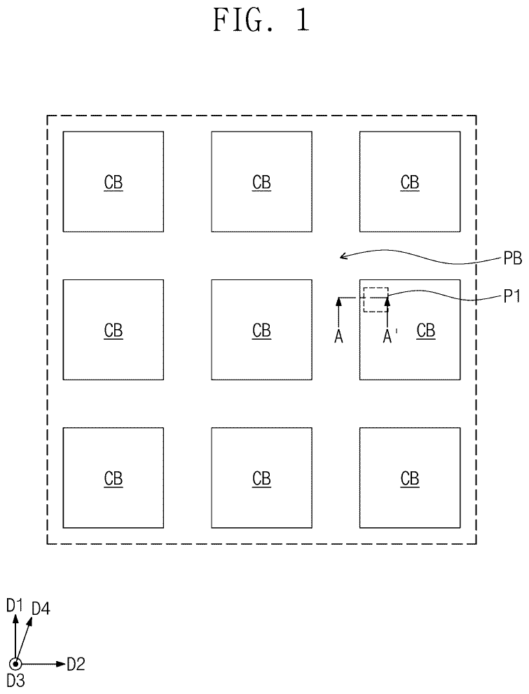

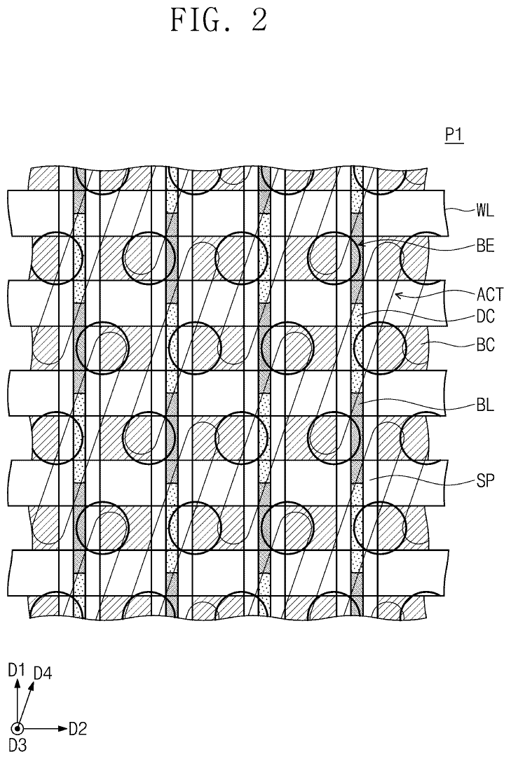

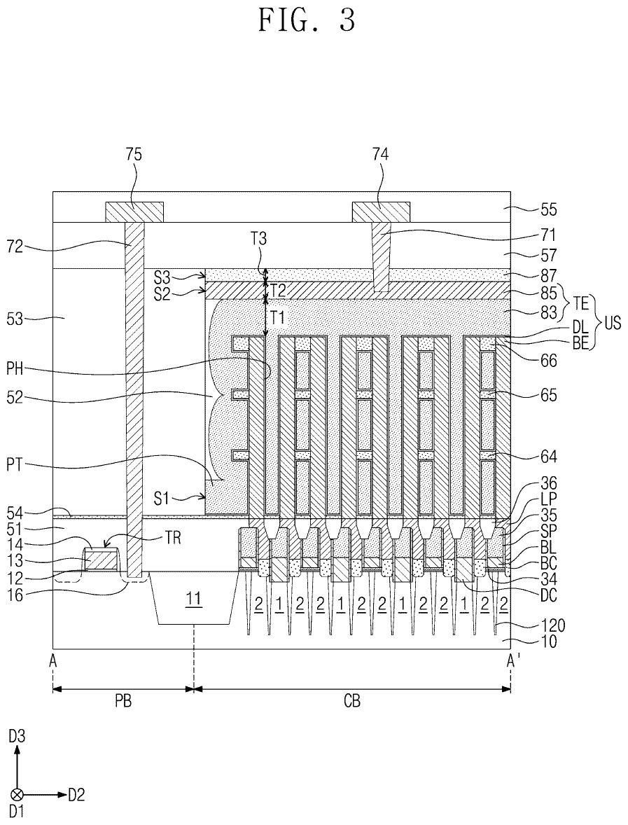

FIG. 1 is a plan view showing a semiconductor device according to some example embodiments of the inventive concepts. FIG. 2 is an enlarged view of region ‘P1’ in FIG. 1. FIG. 3 is a cross-sectional view corresponding to A-A′ in FIG. 1.

Referring to FIG. 1, a semiconductor device may include cell regions CB and a peripheral circuit region PB surrounding each of the cell regions CB. The semiconductor device may be a memory device, and each of the cell regions CB may include a cell circuit such as a memory integrated circuit. The cell regions CB may be spaced apart from each other in a first direction D1 and a second direction D2 that intersects (e.g., perpendicular to) the first direction D1.

The peripheral circuit region PB may include various peripheral circuits necessary for operation of the cell circuit, and the peripheral circuits may be electrically connected to the cell circuit. The peripheral circuit region PB may include sense amplifier circuits and sub-word line driver circuits. For example, the sense amplifier circuits may face each other across the cell regions CB, and the sub-word line driver circuits may face each other across the cell regions CB. The peripheral circuit region PB may further include power and ground driver circuits for driving the sense amplifier, but the inventive concepts are not limited thereto.

Referring to FIGS. 2 and 3, a substrate 10 including a cell region CB and a peripheral circuit region PB may be provided. The cell region CB may be an region of the substrate 10 where each cell region CB of FIG. 1 is provided. The substrate 10 may be, for example, a silicon substrate, a germanium substrate, or a silicon-germanium substrate.

Active patterns ACT may be disposed on the cell region CB of the substrate 10. When viewed in a plan view, the active patterns ACT may be spaced apart from each other in the first direction D1 and the second direction D2. The active patterns ACT are parallel to an upper surface of the substrate 10 and may have a bar shape extending in a fourth direction D4 that intersects the first direction D1 and the second direction D2. An end of one of the active patterns ACT may be arranged to be adjacent to a center of another active pattern ACT that is immediately adjacent thereto in the second direction D2. Each of the active patterns ACT may be a portion of the substrate 10 that protrudes from the substrate 10 in a third direction D3.

First device isolation layers 120 may be disposed between the active patterns ACT. The first device isolation layers 120 may be disposed in the substrate 10 to define the active patterns ACT. For example, the first device isolation layers 120 may include silicon oxide, silicon nitride, and/or silicon oxynitride.

Word lines WL may be disposed in the substrate 10 and may cross the active patterns ACT and the first device isolation layers 120. The word lines WL may be disposed in grooves formed in the active patterns ACT and the first device isolation layers 120. The word lines WL may extend in the second direction D2 and be spaced apart from each other in the first direction D1. The word lines WL may be buried in the substrate 10.

Impurity regions may be provided in the active patterns ACT. The impurity regions may include first impurity regions 1 and second impurity regions 2. The second impurity regions 2 may be provided adjacent to both ends of each of the active patterns ACT. E ach of the first impurity regions 1 may be provided between the second impurity regions 2 in each of the active patterns ACT. The first impurity regions 1 may include impurities of the same conductivity type (e.g., N-type) as the second impurity regions 2.

A buffer pattern 34 may be disposed on the cell region CB of the substrate 10. The buffer pattern 34 may cover the active patterns ACT, the first device isolation layers 120, and the word lines WL. For example, the buffer pattern 34 may include silicon oxide, silicon nitride, and/or silicon oxynitride.

Bit lines BL may be disposed on the substrate 10. The bit lines BL may extend in the first direction D1 and may be spaced apart from each other in the second direction D2. Each of the bit lines BL may include an ohmic pattern and a metal-containing pattern that are sequentially stacked. As an example, the ohmic pattern may include metal silicide. As an example, the metal-containing pattern may include metal (tungsten, titanium, tantalum, etc.). Semiconductor patterns, for example, polysilicon patterns, may be interposed between the bit lines BL and the buffer pattern 34.

Bit line contacts DC may be interposed on each of the first impurity regions 1. The bit lines BL may be electrically connected to the first impurity regions 1 through the bit line contacts DC. The bit line contacts DC may include polysilicon doped with impurities or undoped.

The bit line contacts DC may be disposed in the recess region. The recess region may be provided on an upper portion of the first impurity regions 1 and on an upper portion of the first device isolation layers 120 adjacent thereto.

A bit line capping pattern 35 may be provided on an upper surface of each of the bit lines BL. The bit line capping pattern 35 may extend in the first direction D1 on each of the bit lines BL, and may be spaced apart from neighboring bit line capping patterns 35 in the second direction D2. The bit line capping pattern 35 may include a silicon nitride layer.

A bit line spacer SP may be provided on each side surface of the bit line contacts DC and the bit lines BL. The bit line spacer SP may extend in the first direction D1 in each of the bit lines BL. The bit line spacer SP may include a plurality of insulating layers. As an example, the bit line spacer SP may include a silicon oxide layer and a silicon nitride layer. The bit line spacer SP may include an air gap, which is a substantially empty space, therein.

Storage node contacts BC may be interposed between neighboring bit lines BL on the substrate 10. The bit line spacer SP may be interposed between the storage node contacts BC and the bit lines BL adjacent thereto. The storage node contacts BC may be spaced apart from each other in the first direction D1 and the second direction D2. Each of the storage node contacts BC may be electrically connected to a corresponding one of the second impurity regions 2. The storage node contacts BC may include polysilicon doped with impurities or undoped.

Landing pads LP may be disposed on each of the storage node contacts BC. Each of the landing pads LP may be electrically connected to a corresponding one of the storage node contacts BC. The landing pads LP may include a metal-containing material such as tungsten. Upper portions of the landing pads LP may be shifted from the storage node contacts BC in the second direction D2. When viewed in a plan view, the landing pads LP may be spaced apart from each other in the first direction D1 and the second direction D2. For example, the landing pads LP may be spaced apart from each other in the first direction D1 and the second direction D2 in a zigzag shape.

An ohmic pattern may be provided between landing pads LP and the storage node contacts BC. The ohmic pattern may include metal silicide.

A filling pattern 36 may surround each of the landing pads LP. The filling pattern 36 may be interposed between adjacent landing pads LP. As an example, the filling pattern 36 may include at least one of silicon nitride, silicon oxide, or silicon oxynitride. As another example, the filling pattern 36 may include an empty region.

The cell region CB and the peripheral circuit region PB may be spaced apart from each other by a second device isolation layer 11 formed on the substrate 10. For example, the second device isolation layer 11 may include silicon oxide, silicon nitride, and/or silicon oxynitride. A peripheral transistor TR may be provided in the peripheral circuit region PB. The peripheral transistor TR may be a transistor constituting sense amplifier circuits or sub-word line driver circuits. The peripheral transistor TR may include a gate electrode 13, a gate insulating layer 12, source/drain regions 16, and a gate capping pattern 14.

A first interlayer insulating layer 51 may be provided covering the peripheral transistor TR. The first interlayer insulating layer 51 may include a silicon oxide layer. The first interlayer insulating layer 51 may include silicon oxide, silicon nitride, and/or silicon oxynitride. The first interlayer insulating layer 51 may extend into the cell region CB.

An etch stop pattern 54 may be disposed on the filling pattern 36. The etch stop pattern 54 may expose upper surfaces of the landing pads LP. The etch stop pattern 54 may include at least one of silicon nitride, silicon carbonitride, or silicon oxynitride. The etch stop pattern 54 extends into the peripheral circuit region PB and may cover the first interlayer insulating layer 51.

Lower electrodes BE may be disposed on upper surfaces of the landing pads LP, respectively. Each of the lower electrodes BE may be electrically connected to a corresponding one of the landing pads LP. The lower electrodes BE may penetrate the etch stop pattern 54. For example, each of the lower electrodes BE may have a pillar shape. As another example, although not shown, each of the lower electrodes BE may have a cylinder shape with a closed bottom surface.

The lower electrodes BE may be spaced apart from each other in the first direction D1 and the second direction D2. As shown in FIG. 2, the lower electrodes BE may be arranged to have a honeycomb shape. In detail, with one lower electrode BE at a center, six lower electrodes BE may be arranged to surround the one lower electrode BE in a hexagon. The lower electrodes BE may include a conductive material. For example, the lower electrodes BE may include at least one of a metal material (e.g., cobalt, titanium, nickel, tungsten, and molybdenum), metal nitride (e.g., titanium nitride (TiN), titanium silicon dioxide (TiSiN), titanium aluminum nitride (TiAlN), tantalum nitride (TaAlN), and tungsten nitride (WN)), a precious metal (e.g., platinum (Pt), ruthenium (Ru), and iridium (Ir)), conductive oxide (PtO, RuO₂, IrO₂, SrRuO₃ (SRO), (Ba,Sr) RuO₃ (BSRO), CaRuO₃ (CRO), LSCo), or metal silicide.

Support patterns may be provided on the substrate 10. The support patterns may include a first support pattern 64, a second support pattern 65, and a third support pattern 66 spaced apart from each other in the third direction D3. Although three support patterns are described as being provided, fewer or more support patterns may be provided. The first support pattern 64, the second support pattern 65, and the third support pattern 66 may be sequentially arranged in the third direction D3. Each of the support patterns 64, 65, and 66 may include, for example, at least one of silicon nitride, SiBN, or SiCN. The third support pattern 66 may be thicker than the first support pattern 64 and the second support pattern 65, but alternatively, the first support pattern 64, the second support pattern 65, and the third support pattern 66 may have the same thickness.

When viewed in a plan view, each of the support patterns 64, 65, and 66 may be interposed between one of the lower electrodes BE and a neighboring lower electrode BE. Each of the support patterns 64, 65, and 66 may be provided on sidewalls of the lower electrodes BE. Each of the support patterns 64, 65, and 66 may include through holes PH exposing portions of the sidewalls of the lower electrodes BE. As an example, one through hole PH may be arranged in a circular shape between three adjacent lower electrodes BE, and may partially expose a side surface of each of the three lower electrodes BE. However, the inventive concepts are not limited thereto, and the through holes PH may be arranged between the plurality of lower electrodes BE in various shapes.

An upper electrode TE may cover the lower electrodes BE and the support patterns 64, 65, and 66. A dielectric layer DL may be interposed between the lower electrodes BE and the upper electrode TE, and between the support patterns 64, 65, and 66 and the upper electrode TE. The dielectric layer DL may conformally cover the lower electrodes BE and the support patterns 64, 65, and 66. The dielectric layer DL may cover an upper surface of the etch stop pattern 54 in the cell region CB. The dielectric layer DL may have the same crystal structure as that of the lower electrodes BE. For example, the dielectric layer DL may have a tetragonal structure. The dielectric layer DL may be formed of any single layer selected from, for example, a metal oxide such as HfO₂, ZrO₂, Al₂O₃, La₂O₃, Ta₂O₃, and TiO₂, and pervoskite such as SrTiO₃ (STO), (Ba,Sr) TiO₃ (BST), BaTiO₃, PZT, and PLZT or a combination of these layers.

The upper electrode TE may cover the lower electrodes BE and the support patterns 64, 65, and 66. The upper electrode TE may fill space between the lower electrodes BE through the through holes PH. The lower electrodes BE, the dielectric layer DL, and the upper electrode TE may form a capacitor US. As an example, the capacitor US may function as a data storage element for the semiconductor device according to the inventive concepts to operate as a memory device.

The upper electrode TE may include a first pattern 83 covering the upper surface and sidewalls of the lower electrodes BE and a second pattern 85 on the first pattern 83. The first pattern 83 may include a sidewall portion covering the side surfaces of the upper and lower electrodes BE on the upper surface of the lower electrodes BE. That is, the first pattern 83 may extend from the upper surface of the lower electrodes BE to the side surfaces of the lower electrodes BE. A sidewall portion of the first pattern 83 may have concave-convex shape due to a shape of the sidewalls of the lower electrodes BE and the sidewalls of the support patterns 64, 65, and 66.

The first pattern 83 may include a protrusion PT that is positioned at a lower level of the lower electrodes BE and extends from the sidewall thereof. The protrusion PT may protrude from the sidewall toward the peripheral circuit region PB. The first pattern 83 may include a doped semiconductor material. As an example, the first pattern 83 may include polysilicon doped with an impurity or silicon germanium doped with an impurity. The first pattern 83 may further include a metal material such as tungsten and/or a metal nitride such as tungsten nitride.

The second pattern 85 may cover an upper portion of the first pattern 83, but may be exposed without covering the sidewall portion of the first pattern 83. That is, the lowermost surface of the second pattern 85 may be at the same level as an upper surface of the first pattern 83. The second pattern 85 may include at least one of metal, metal nitride, and/or doped semiconductor. As an example, the second pattern 85 may include tungsten, tungsten nitride, or doped silicon germanium.

A mask pattern 87 may be provided on the second pattern 85. The mask pattern 87 may include at least one of SiON or silicon. As an example, the mask pattern 87 may include doped or undoped silicon. At least a portion of the mask pattern 87 may be amorphous silicon. The mask pattern 87 may cover an upper surface of the second pattern 85, but may expose the sidewall portion of the first pattern 83 without covering it. That is, the lowermost surface of the mask pattern 87 may be at the same level as the upper surface of the second pattern 85. A lower surface of the mask pattern 87 may be in contact with the upper surface of the second pattern 85, and the lower surface of the second pattern 85 may be in contact with the upper surface of the first pattern 83.

An end S1 of the first pattern 83, an end S2 of the second pattern 85, and an end S3 of the mask pattern 87 may be substantially aligned (e.g. coplanar) in a third direction perpendicular to the upper surface of the substrate 10. This may be because the ends S1 to S3 of the first pattern 83, the second pattern 85, and the mask pattern 87 are formed simultaneously through an etching process to be described below. A thickness T2 of the second pattern 85 may be thinner than a thickness T1 of the first pattern 83. For example, the thickness T2 of the second pattern 85 may be about 0.5 to 0.9 times the thickness T1 of the first pattern 83. For example, T1 may be a thickness of the first pattern 83 that vertically overlaps the lower electrodes BE. A thickness T3 of the mask pattern 87 may be thinner than the thickness T2 of the second pattern 85. For example, the thickness T3 of the mask pattern 87 may be about 0.7 to 0.9 times the thickness T2 of the second pattern 85. Alternatively, the thickness T3 of the mask pattern 87 may be the same as the thickness T2 of the second pattern 85.

A second interlayer insulating layer 52 and a third interlayer insulating layer 53 may be provided on the etch stop pattern 54 in the peripheral circuit region PB. The second interlayer insulating layer 52 may be provided between the third interlayer insulating layer 53 and the sidewall portion of the first pattern 83. A portion of the second interlayer insulating layer 52 may extend between the first pattern 83 and the second pattern 85. For example, a sidewall of the second interlayer insulating layer 52 may be aligned (e.g. coplanar) with at least one of the end S1 of the first pattern 83, the end S2 of the second pattern 85, and the end of the mask pattern 87. The third interlayer insulating layer 53 may cover the end S1 of the first pattern 83, the end S2 of the second pattern 85, and the end of the mask pattern 87.

A fourth interlayer insulating layer 57 may be provided covering an upper surface of the third interlayer insulating layer 53 and an upper surface of the mask pattern 87, and a fifth interlayer insulating layer 55 may be provided on the fourth interlayer insulating layer 57. The second interlayer insulating layer 52, the third interlayer insulating layer 53, the fourth interlayer insulating layer 57, and the fifth interlayer insulating layer 55 may include silicon oxide, silicon nitride, and/or silicon oxynitride.

A cell contact plug 71 may be provided that penetrates the fourth interlayer insulating layer 57 and is connected to an upper portion of the upper electrode TE. The cell contact plug 71 may penetrate the mask pattern 87 and be connected to the second pattern 85. Although only one cell contact plug 71 is shown, a plurality of cell contact plugs 71 may be provided. A peripheral contact plug 72 may be provided that penetrates the first interlayer insulating layer 51, the third interlayer insulating layer 53, and the fourth interlayer insulating layer 57 and is connected to the peripheral transistor TR. For example, the peripheral contact plug 72 may be connected to the source/drain region 16 of the peripheral transistor TR, but alternatively, it may be connected to the gate electrode 13 of the peripheral transistor TR. The peripheral contact plug 72 may penetrate the etch stop pattern 54. The peripheral contact plug 72 and the cell contact plug 71 may include a metal layer and a metal nitride layer. For example, the peripheral contact plug 72 and the cell contact plug 71 may include tungsten, titanium, tantalum, and/or nitride layers thereof. The peripheral contact plug 72 and the cell contact plug 71 may have a shape whose width decreases as it approaches the substrate 10.

For example, the end S1 of the first pattern 83, the end S2 of the second pattern 85, and the end S3 of the mask pattern 87 may be opposite (e.g. may face) the peripheral contact plug 72.

A first wiring 74 connected to the cell contact plug 71 and a second wiring 75 connected to the peripheral contact plug 72 may be provided in the fifth interlayer insulating layer 55. For example, the first wiring 74 and the second wiring 75 may include copper or aluminum.

According to some example embodiments of the inventive concepts, a distance between the peripheral contact plug 72 and the sidewall portion of the first pattern 83 may not be affected by the thickness of the second pattern 85. When the distance between the peripheral contact plug 72 and the upper electrode TE is relatively small, a short circuit may occur between the peripheral contact plug 72 and the upper electrode TE or a leakage current may occur. According to some example embodiments of the inventive concepts, the separation distance between the peripheral contact plug 72 and the upper electrode TE may be secured, thereby improving electrical characteristics of the semiconductor device and increasing integration thereof.

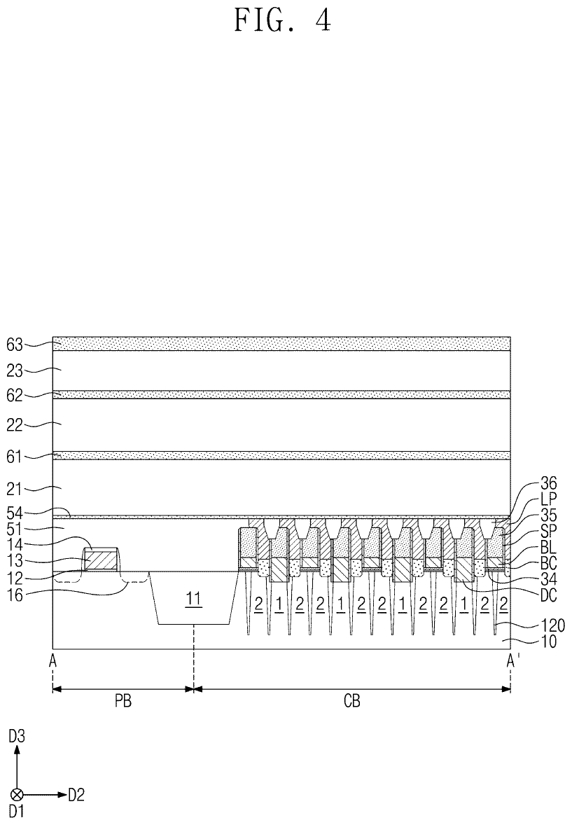

FIGS. 4 to 10 are cross-sectional views for explaining a method of manufacturing a semiconductor device according to some example embodiments of the inventive concepts. To simplify explanation, descriptions of overlapping configurations may be omitted.

Referring to FIG. 4, a substrate 10 including a cell region CB and a peripheral circuit region PB may be provided. The substrate 10 may be a semiconductor substrate. The substrate 10 may be, for example, a silicon substrate, a germanium substrate, or a silicon-germanium substrate. First device isolation layers 120 may be formed on the cell region CB, and a second device isolation layer 11 may be formed between the cell region CB and the peripheral circuit region PB. Bit line contacts DC, bit lines BL, storage node contacts BC, bit line capping patterns 35, and landing pads LP may be formed on the cell region CB. A filling pattern 36 may be formed between the landing pads LP. A peripheral transistor TR may be formed on the peripheral circuit region PB.

A first interlayer insulating layer 51 and an etch stop pattern 54 covering the cell region CB and the peripheral circuit region PB may be formed. The etch stop pattern 54 may be disposed on the first interlayer insulating layer 51. The etch stop pattern 54 may include at least one of silicon oxide, SiCN, or SiBN.

A mold structure may be formed on the etch stop pattern 54. The mold structure may be formed by alternately stacking mold layers and support layers. As an example, the mold structure includes a first mold layer 21, a first support layer 61, a second mold layer 22, a second support layer 62, a third mold layer 23, and it may include a third support layer 63. The first to third mold layers 21, 22, and 23 may include a material that has etch selectivity with respect to the first to third support layers 61, 62, and 63 and may be selectively removed. The first to third mold layers 21, 22, and 23 may contain the same material. The first to third support layers 61, 62, and 63 may include the same material. As an example, the first to third mold layers 21, 22, and 23 may include silicon oxide. The first to third support layers 61, 62, and 63 may include at least one of silicon nitride, SiBN, or SiCN.

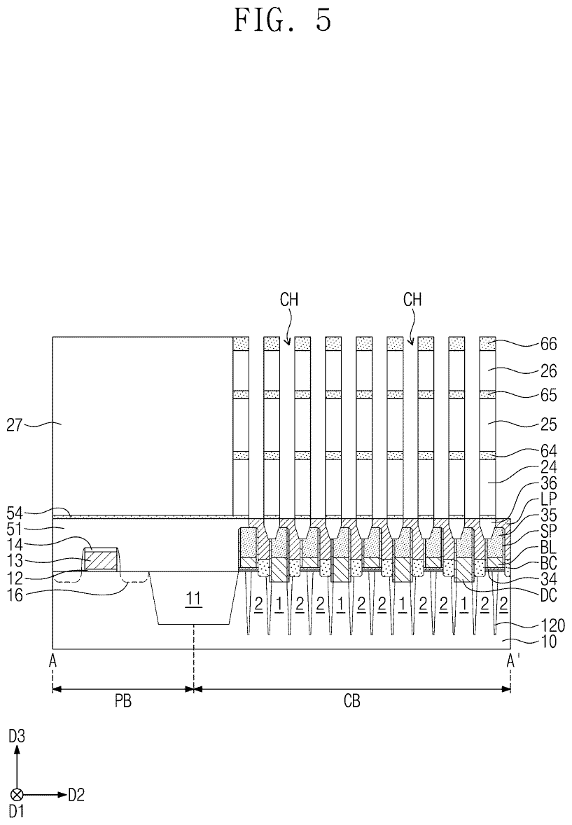

Referring to FIG. 5, a fourth mold pattern 27 may be formed after removing the mold structure on the peripheral circuit region PB. The fourth mold pattern 27 may be formed of the same material as the first to third mold layers 21, 22, and 23. Afterwards, the mold structure on the cell region CB may be patterned to form through holes CH. A shape of the through holes CH may be circular when viewed in a plan, but is not limited thereto. By forming the through holes CH, the first to third mold layers 21, 22, and 23 may become the first to third mold patterns 24, 25, and 26, and the first to third mold layers 21, 22, and 23 may become the first to third mold patterns 24, 25, and 26. The support layers 61, 62, and 63 may become first to third support patterns 64, 65, and 66.

Forming the through holes CH may include a dry etching process using a mask pattern including openings. The mask pattern may include at least one of polysilicon, silicon nitride, or silicon oxynitride. The through holes CH may be formed until the through holes CH penetrate the etch stop pattern 54. As a result, each of the through holes CH may expose an upper surface of the landing pads LP.

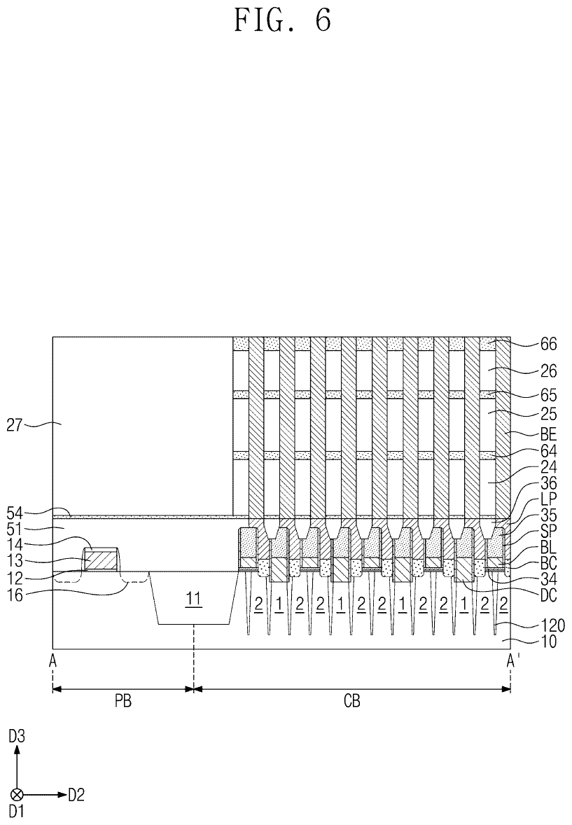

Referring to FIG. 6, lower electrodes BE may be formed in the through holes CH. Forming the lower electrodes BE may include forming an electrode layer that fills the through holes CH. The electrode layer may be formed through a deposition technology with excellent step coverage. As an example, the electrode layer may be formed through a chemical vapor deposition (CVD) or atomic layer deposition (ALD) process.

As an example, the electrode layer may be formed to completely fill the through holes CH. As another example, although not shown, the electrode layer may be formed to conformally cover inner walls of each of the through holes CH and an upper surface of the mold structure. The electrode layer may include at least one of a metal material (e.g., cobalt, titanium, nickel, tungsten, and molybdenum), metal nitride (e.g., titanium nitride (TiN), titanium silicon dioxide (TiSiN), titanium aluminum nitride (TiAlN), tantalum nitride (TaAlN), and tungsten nitride (WN)), a precious metal (e.g., platinum (Pt), ruthenium (Ru), and iridium (Ir)), conductive oxide (PtO, RuO₂, IrO₂, SrRuO₃ (SRO), (Ba,Sr) RuO₃ (BSRO), CaRuO₃ (CRO), LSCo), or metal silicide.

Afterwards, an upper portion of the electrode layer may be removed and separated into lower electrodes BE that fill each of the through holes CH. Removing the upper portion of the electrode layer may include, for example, performing an etch-back process. The lower electrodes BE may be connected to upper surfaces of the landing pads LP, respectively. Although not shown, when the electrode layer is formed to conformally cover the inner wall of each of the through holes CH, each of the lower electrodes BE may be formed to have a cylinder shape with a closed bottom surface.

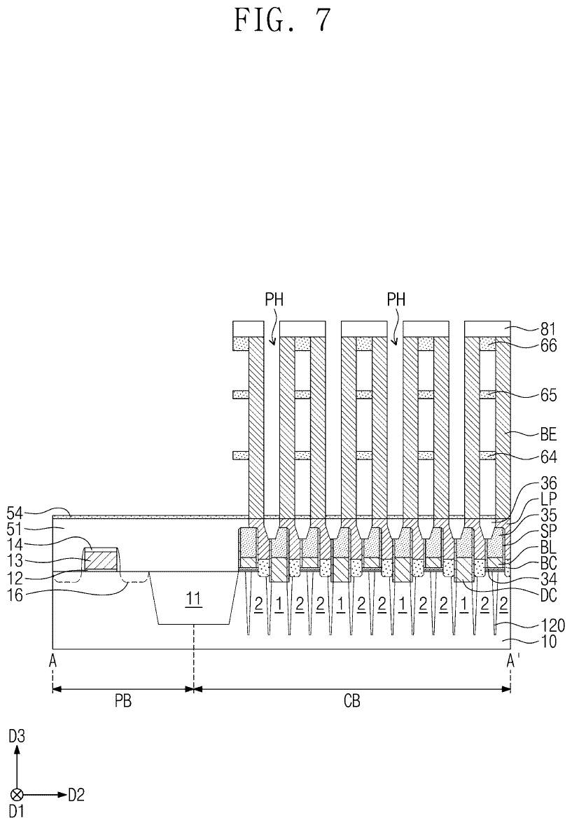

Referring to FIG. 7, after forming a mask pattern 81 exposing a portion of the upper surface of the third support pattern 66, the third support pattern 66 may be patterned using the mask pattern 81 to form a through holes PH. As a result, an upper surface of the third mold pattern 26 may be exposed. The third mold pattern 26 with the upper surface thereof exposed may be selectively removed, and thus a portion of an upper surface of the second support pattern 65 may be exposed. Afterwards, through holes PH may be formed in the exposed portion of the second support pattern 65, and thus the exposed second mold pattern 25 may be selectively removed. Likewise, through holes PH may be formed in the first support pattern 64 exposed by removing the second mold pattern 25, and thus the exposed first mold pattern 24 may be selectively removed. The fourth mold pattern 27 may be removed together with the first to third mold patterns 24, 25, and 26.

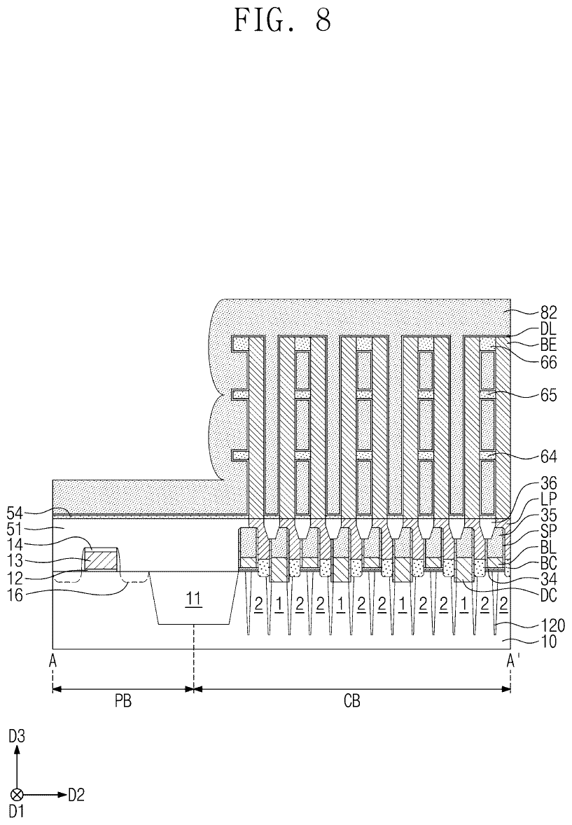

Referring to FIG. 8, after removing the mask pattern 81, a dielectric layer DL and a first electrode layer 82 may be formed sequentially. The dielectric layer DL may cover the exposed surfaces of the lower electrodes BE and the first to third support patterns 64, 65, and 66. The dielectric layer DL may extend into the peripheral circuit region PB and cover the etch stop pattern 54. The first electrode layer 82 may cover the upper surfaces of the lower electrodes BE in the cell region CB and may extend to the peripheral circuit region PB. The first electrode layer 82 may fill a space between the lower electrodes BE and the first to third support patterns 64, 65, and 66. The first electrode layer 82 may be formed on the dielectric layer DL. The first electrode layer 82 may be formed of either polysilicon doped with an impurity or silicon germanium doped with an impurity. The first electrode layer 82 may cover sidewalls of the first to third support patterns 64, 65, and 66 and sidewalls of the lower electrodes BE between the cell region CB and the peripheral circuit region PB, and may include concave-convex portions that are not flat due to the sidewalls of the first to third support patterns 64, 65, and 66.

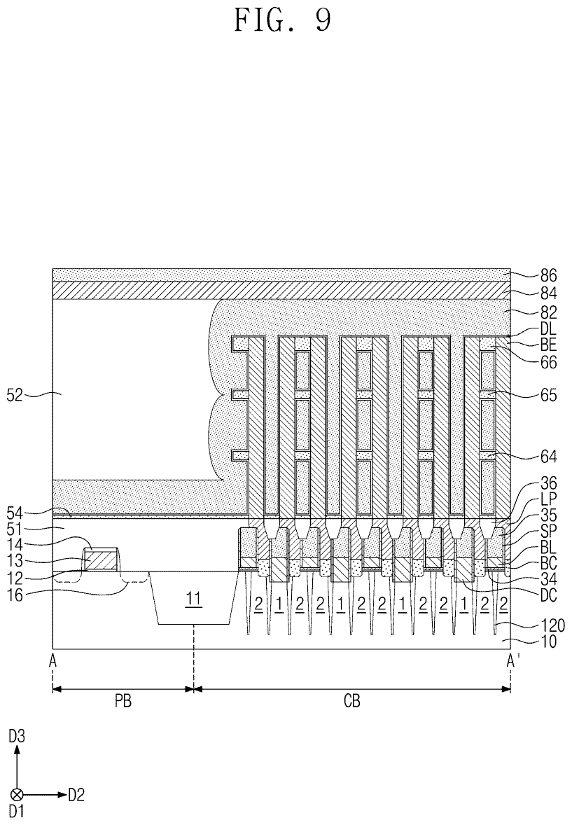

Referring to FIG. 9, a second interlayer insulating layer 52 may be formed to cover the first electrode layer 82. After forming the second interlayer insulating layer 52 to cover both the cell region CB and the peripheral circuit region PB, a planarization process may be performed to expose the first electrode layer 82 in the cell region CB. The planarization process may be a chemical mechanical polishing process. The second interlayer insulating layer 52 may be formed of silicon oxide, silicon nitride, and/or silicon oxynitride.

A second electrode layer 84 may be formed to cover the second interlayer insulating layer 52 and the exposed first electrode layer 82, and a mask layer 86 may be formed on the second electrode layer 84. The second electrode layer 84 may be formed of at least one of metal, metal nitride, and/or doped semiconductor. For example, the second electrode layer 84 may be formed of tungsten, tungsten nitride, or doped silicon germanium. The mask layer 86 may be formed of doped or undoped silicon. The mask layer 86 may be amorphous.

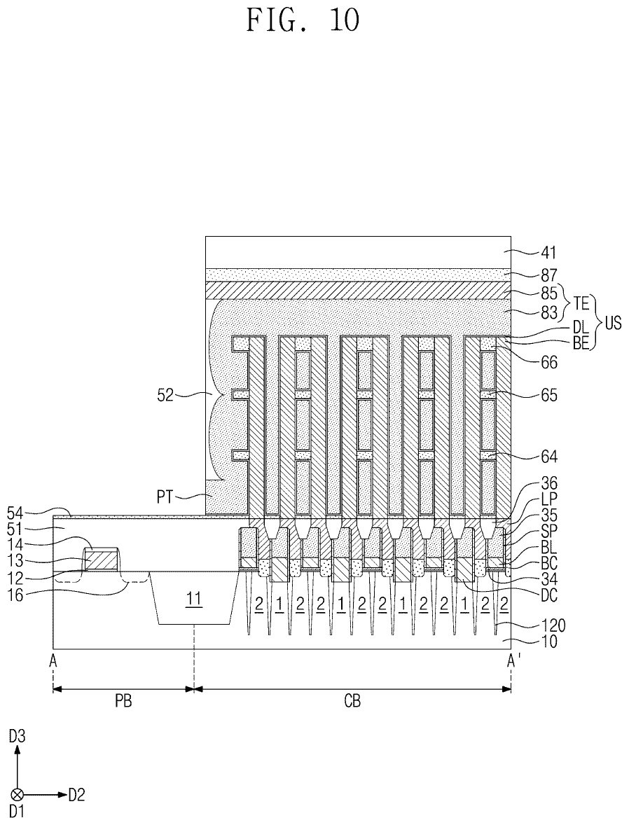

Referring to FIG. 10, after forming a photoresist pattern 41, the mask layer 86, the second electrode layer 84, the second interlayer insulating layer 52, and the first electrode layer 82 may be sequentially etched using the photoresist pattern 41 as an etch mask. As an example, the etching process may include a dry etching process. Accordingly, a mask pattern 87, a second pattern 85, and a first pattern 83 may be formed. As a result of the etching process, a protrusion PT may be formed in the first pattern 83. The mask layer 86, the second electrode layer 84, and the first electrode layer 82 may be sequentially patterned with the same etch mask pattern, and thus an end of the first pattern 83, an end of the second pattern 85, and an end of the mask pattern 87 may be substantially aligned (e.g. co-planar) in the third direction D3, which is a direction perpendicular to an upper surface of the substrate 10. The first pattern 83 and the second pattern 85 may form an upper electrode TE, and the upper electrode TE, the dielectric layer DL, and the lower electrodes BE may constitute a capacitor US. The remainder of the second interlayer insulating layer 52 may remain on a sidewall of the first pattern 83. When forming the upper electrode TE, the dielectric layer DL on the peripheral circuit region PB may be removed together.

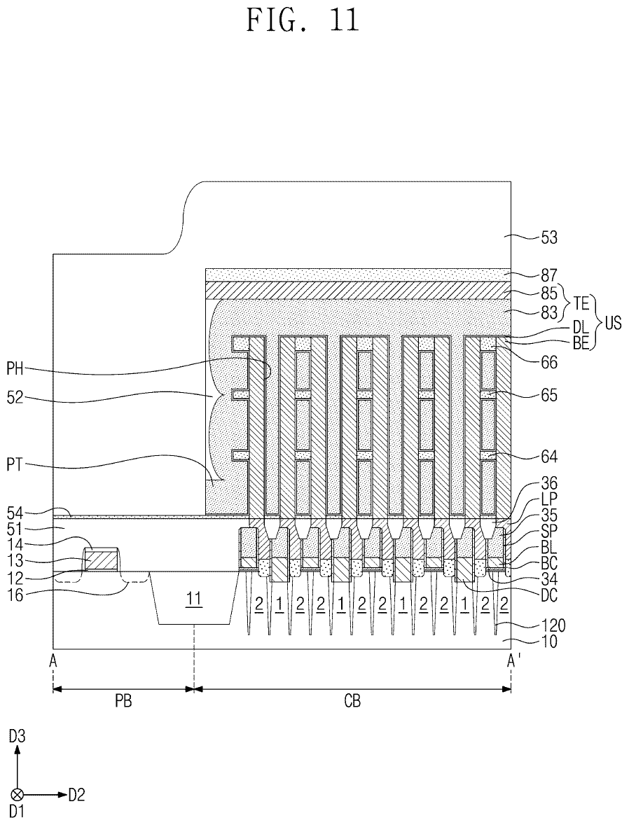

Referring to FIG. 11, a third interlayer insulating layer 53 may be formed covering the cell region CB and the peripheral circuit region PB. The third interlayer insulating layer 53 may cover the mask pattern 87 in the cell region CB and the etch stop pattern 54 in the peripheral circuit region PB.

Referring again to FIG. 3, after performing a planarization process on the third interlayer insulating layer 53 to expose the mask pattern 87, a fourth interlayer insulating layer 57 may be formed. A cell contact plug 71 may be formed through the fourth interlayer insulating layer 57 and the mask pattern 87 and connected to the upper electrode TE. A peripheral contact plug 72 connected to the peripheral transistor TR may be formed through the fourth interlayer insulating layer 57, the third interlayer insulating layer 53, and the first interlayer insulating layer 51. The cell contact plug 71 and the peripheral contact plug 72 may be formed together of the same material, but are not limited thereto.

After forming first and second wirings 74 and 75 respectively connected to the cell contact plug 71 and the peripheral contact plug 72, a fifth interlayer insulating layer 55 may be formed to cover them.

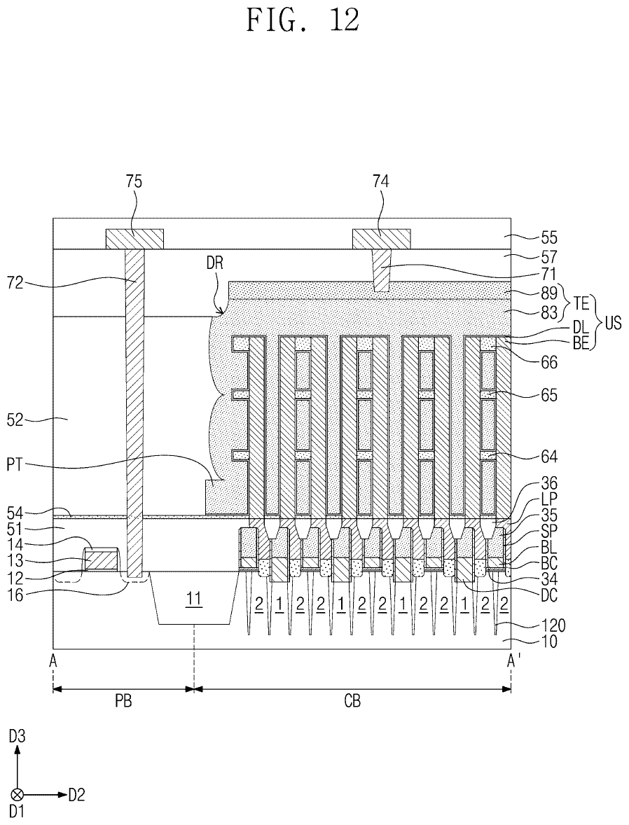

FIG. 12 is a cross-sectional view of a semiconductor device according to some example embodiments of the inventive concepts. To simplify explanation, descriptions of overlapping configurations may be omitted.

Referring to FIG. 12, the upper electrode TE of the capacitor US may include a first pattern 83 and a second pattern 89. The second pattern 89 may cover and upper portion of the first pattern 83, but may be exposed without covering the sidewall portion of the first pattern 83. An end of the second pattern 89 may not be aligned with the end of the first pattern 83. As an example, the end of the second pattern 89 may be provided on the first pattern 83. The second pattern 89 may be thinner than the first pattern 83. The first pattern 83 may include a depression DR at a position adjacent to the end of the second pattern 89.

The second pattern 89 may include at least one of metal, metal nitride, and/or doped semiconductor. As an example, the second pattern 89 may include tungsten, tungsten nitride, or doped silicon germanium. A lower surface of the cell contact plug 71 on the second pattern 89 may be provided in the second pattern 89.

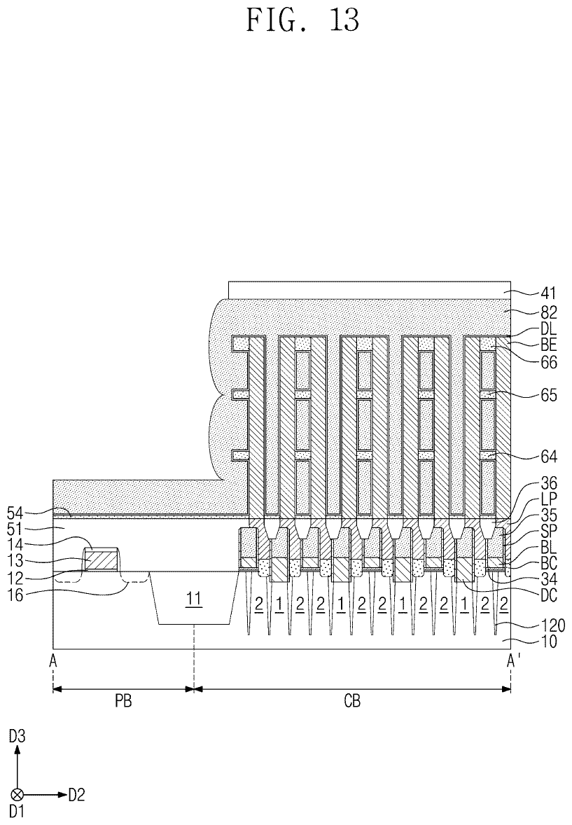

FIGS. 13 to 15 are cross-sectional views for explaining a method of manufacturing a semiconductor device according to some example embodiments of the inventive concepts.

Referring to FIG. 13, a photoresist pattern 41 may be formed that covers a portion of the first electrode layer 82 described with reference to FIG. 8. The photoresist pattern 41 may be formed on the cell region CB and may not be formed on the peripheral circuit region PB.

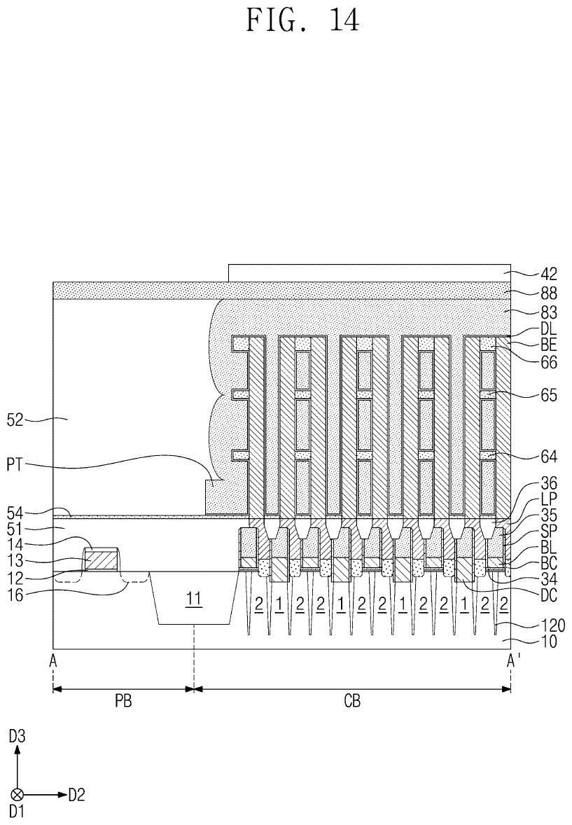

Referring to FIG. 14, the first electrode layer 82 may be patterned by performing an etching process using the photoresist pattern 41 to form the first pattern 83. As a result of patterning, a protrusion PT may be formed in the first pattern 83. After forming the second interlayer insulating layer 52 to cover both the cell region CB and the peripheral circuit region PB, a planarization process may be performed to expose the first pattern 83 in the cell region CB. The planarization process may be a chemical or physical polishing process.

A second electrode layer 88 may be formed to cover the second interlayer insulating layer 52 and the exposed first pattern 83, and a second photoresist pattern 42 may be formed on the second electrode layer 88. The second electrode layer 88 may be formed of at least one of metal, metal nitride, and/or doped semiconductor. For example, the second electrode layer 88 may be formed of tungsten, tungsten nitride, or doped silicon germanium.

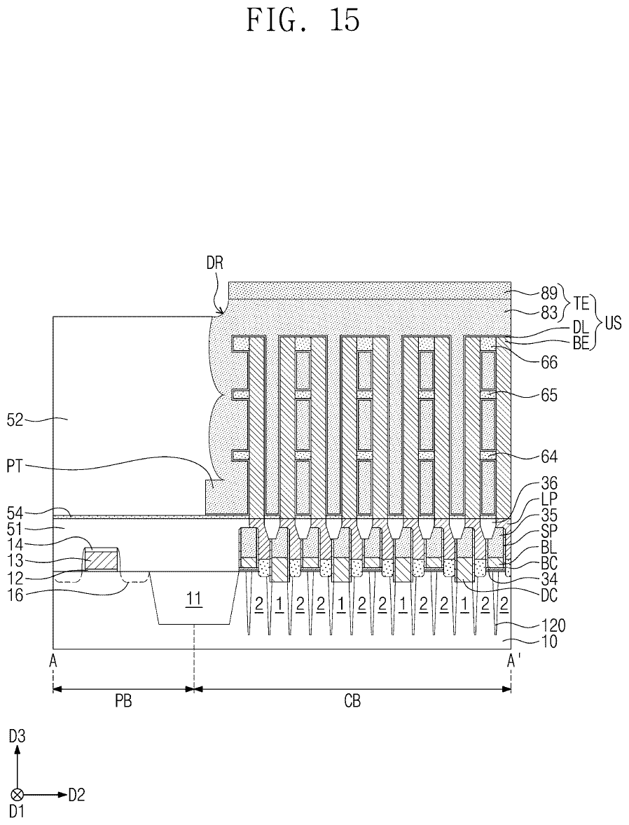

Referring to FIG. 15, the second electrode layer 88 may be patterned by performing an etching process using the second photoresist pattern 42 to form the second pattern 89. During the etching process, an upper portion of the first pattern 83 and an upper portion of the second interlayer insulating layer 52 may be etched together to form a depression DR in the first pattern 83. For example, the first pattern 83 and the second pattern 89 in the depression DR may be spaced apart from the peripheral contact plug 72 at a distance greater than a distance between the first pattern 83 outside of the depression region DR and the contact plug 72.

Referring again to FIG. 12, after forming the fourth interlayer insulating layer 57 covering the second pattern 89 and the second interlayer insulating layer 52, forming the cell contact plug 71, the peripheral contact plug 72, the first wiring 74, and the second wiring 75 described with reference to FIG. 3 may be performed.

According to the inventive concepts, the separation distance between the peripheral contact plug and the upper electrode may be secured, thereby improving the electrical characteristics of the semiconductor device and increasing the integration.

While some example embodiments are described above, a person skilled in the art may understand that many modifications and variations are made without departing from the spirit and scope of the inventive concept defined in the following claims. Accordingly, the example embodiments of the inventive concepts should be considered in all respects as illustrative and not restrictive, with the spirit and scope of the inventive concept being indicated by the appended claims.

What is claimed is:

1. A semiconductor device comprising:
lower electrodes on a substrate;
a dielectric layer covering the lower electrodes;
an upper electrode on the dielectric layer; and
a mask pattern on the upper electrode,
wherein the upper electrode includes,
a first pattern covering upper surfaces and sidewalls of the lower electrodes, and
a second pattern on the first pattern, and
wherein an end of the first pattern, an end of the second pattern, and an end of the mask pattern are aligned in a direction perpendicular to the substrate.

2. The semiconductor device of claim 1, wherein a thickness of the second pattern is smaller than a thickness of the first pattern.

3. The semiconductor device of claim 1, wherein the second pattern includes at least one of a metal, a metal nitride, or a semiconductor.

4. The semiconductor device of claim 1, wherein the mask pattern is thinner than the second pattern.

5. The semiconductor device of claim 1, wherein the mask pattern includes at least one of a SiON layer or a silicon layer.

6. The semiconductor device of claim 5, wherein at least a portion of the mask pattern is amorphous silicon.

7. The semiconductor device of claim 1, further comprising:
an interlayer insulating layer on the substrate,
wherein the interlayer insulating layer extends between the first pattern and the second pattern.

8. The semiconductor device of claim 1,
wherein the semiconductor device includes a cell region and a peripheral circuit region,
wherein the upper electrode is in the cell region,
wherein the peripheral circuit region includes a peripheral transistor and a peripheral contact plug connected to the peripheral transistor, and
wherein the end of the first pattern, the end of the second pattern, and the end of the mask pattern are opposite to the peripheral contact plug.

9. The semiconductor device of claim 1,
wherein a lower surface of the second pattern is in contact with an upper surface of the first pattern, and
wherein a lower surface of the mask pattern is in contact with an upper surface of the second pattern.

10. The semiconductor device of claim 1, further comprising:
a cell contact plug on the mask pattern,
wherein a lower surface of the cell contact plug is in the second pattern.

11. A semiconductor device comprising:
lower electrodes on a substrate;
a dielectric layer covering the lower electrodes; and
an upper electrode on the dielectric layer,
wherein the upper electrode includes,
a first pattern covering upper surface and sidewalls of the lower electrodes, and
a second pattern on the first pattern,
wherein the second pattern is thinner than the first pattern, and
wherein an end of the second pattern is on the first pattern.

12. The semiconductor device of claim 11, wherein the second pattern includes at least one of a metal, a metal nitride, or a semiconductor.

13. The semiconductor device of claim 11,
wherein the first pattern includes a sidewall portion covering the sidewalls of the lower electrodes, and
wherein the second pattern does not cover a sidewall portion of the first pattern.

14. The semiconductor device of claim 11, wherein the first pattern includes a depression at a position adjacent to the end of the second pattern.

15. The semiconductor device of claim 11, further comprising:
a cell contact plug on the second pattern,
wherein a lower surface of the cell contact plug is in the second pattern.

16. The semiconductor device of claim 11,
wherein the semiconductor device includes a cell region and a peripheral circuit region,
wherein the upper electrode is in the cell region,
wherein the peripheral circuit region includes a peripheral transistor and a peripheral contact plug connected to the peripheral transistor,
wherein an end of the first pattern and the end of the second pattern are opposite to the peripheral contact plug.

17. The semiconductor device of claim 11, further comprising:
an interlayer insulating layer on the substrate,
wherein a lower surface of the second pattern is in contact with an upper surface of the first pattern, and
wherein and upper surface of the second pattern is in contact with the interlayer insulating layer.

18. A semiconductor device comprising:
active regions defined by a device isolation layer on a substrate, the active regions including a first impurity region and a second impurity region;
word lines extending in a first direction on the active regions;
capping insulating patterns covering upper surfaces of the word lines, respectively;
bit lines extending on the word lines in a second direction intersecting the first direction;
contact plugs between the bit lines and connected to the second impurity region; and
a capacitor on each of the contact plugs,
wherein the capacitor includes,
lower electrodes on the substrate,
a support pattern between the lower electrodes,
an upper electrode covering the lower electrodes and the support pattern,
a mask pattern on the upper electrode, and
a dielectric layer between lower electrodes and the upper electrode, and between the support pattern and the upper electrode,
wherein the upper electrode includes,
a first pattern covering upper surfaces of the lower electrodes, and
a second pattern covering the first pattern, and
wherein an end of the first pattern, an end of the second pattern, and an end of the mask pattern are aligned in a direction perpendicular to the substrate.

19. The semiconductor device of claim 18, wherein a thickness of the second pattern is smaller than a thickness of the first pattern.

20. The semiconductor device of claim 18, wherein the mask pattern is thinner than the second pattern.
